(19) United States
(12) Patent Application Publication
(10) Pub. No.: US 2026/0066158 A1
(43) Pub. Date: Mar. 5, 2026

(54) CHIP RESISTOR WITH TEMPERATURE SENSING FUNCTION AND MANUFACTURING METHOD THEREOF

(71) Applicant: YAGEO CORPORATION, Kaohsiung City (TW)

(72) Inventors: Shen-Li HSIAO, Kaohsiung City (TW); Suneesh Meledath Valiyaveettil, Kaohsiung City (TW); Ren-Hong Wang, Kaohsiung City (TW)

(21) Appl. No.: 18/963,589

(22) Filed: Nov. 28, 2024

(30) Foreign Application Priority Data
Aug. 27, 2024 (TW) 113132219

(51) Int. Cl. H01C 17/232; G01R 7/16; H01C 1/142; H01C 17/00

(52) U.S. Cl. CPC H01C 17/232; G01R 7/16; H01C 1/142; H01C 17/006

(57) ABSTRACT

A chip resistor with a temperature sensing function is provided. The chip resistor includes a substrate, a resistive layer, a thermosensitive layer, a pair of first electrodes, and a pair of second electrodes. The resistive layer is disposed on a first portion of the substrate. The thermosensitive layer is disposed on a second portion of the substrate, in which a gap is between the resistive layer and the thermosensitive layer. The pair of first electrodes respectively cover two sides of the resistive layer. The pair of second electrodes respectively cover two sides of the thermosensitive layer.

### RELATED APPLICATIONS

This application claims priority to Taiwan Application Serial Number 113132219, filed August 27, 2024, which is herein incorporated by reference.

### BACKGROUND

### Technical Field

The present disclosure relates to a chip resistor and a manufacturing method thereof, and more particularly to a chip resistor with temperature sensing function and manufacturing method thereof.

### Description of Prior Art

Metal film chip resistors are primarily used as electrical sensing elements on printed circuit boards (PCBs), and their resistance values change with temperature changes. Therefore, temperature sensing elements are often required in applications to monitor the ambient temperature. However, the accuracy of the temperature measurement is affected by a number of factors, including the heat dissipation of the environment in which the metal film chip resistor is applied, the thermal conductivity of the insulating material used for the PCB, and the relative distance on the PCB between the metal film chip resistor and the temperature sensing element.

### SUMMARY

In view of the problems of the prior art, the present disclosure provides a chip resistor with a temperature sensing function and a manufacturing method thereof, which may reduce the size of the component and increase the layout space of a printed circuit board (PCB), as well as improve the accuracy of the temperature sensing.

The present disclosure provides a chip resistor with a temperature sensing function, including a substrate, a resistive layer, a thermosensitive layer, a pair of first electrodes and a pair of second electrodes. The resistive layer is disposed on a first portion of the substrate. The thermosensitive layer is disposed on a second portion of the substrate, in which a gap is between the resistive layer and the thermosensitive layer. The pair of first electrodes respectively cover two sides of the resistive layer. The pair of second electrodes respectively cover two sides of the thermosensitive layer.

According to one embodiment of the present disclosure, a material of the thermosensitive layer is a positive temperature coefficient material.

According to one embodiment of the present disclosure, a material of the thermosensitive layer is a negative temperature coefficient material.

According to one embodiment of the present disclosure, a distance of the gap is from 50 microns to 200 microns.

According to one embodiment of the present disclosure, the gap is uniform.

According to one embodiment of the present disclosure, the chip resistor further includes a protection layer. The protection layer covers a portion surface of the resistive layer, a portion surface of the thermosensitive layer, and the gap.

According to one embodiment of the present disclosure, each of the pair of first electrodes includes a copper layer. The copper layer is at least 5 microns thicker than the protective layer.

According to one embodiment of the present disclosure, an area of the resistive layer is larger than an area of the thermosensitive layer in a frontal view.

According to one embodiment of the present disclosure, a volume of each of the pair of first electrodes is greater than a volume of each of the pair of second electrodes.

According to one embodiment of the present disclosure, the resistive layer has a first resistive trimming area.

According to one embodiment of the present disclosure, the thermosensitive layer has a second resistive trimming area.

According to one embodiment of the present disclosure, the chip resistor further includes a pair of first internal electrodes. The pair of first internal electrodes contact the resistive layer and are respectively covered by the pair of first electrodes. The pair of second internal electrodes contact the thermosensitive layer and are respectively covered by the pair of first electrodes.

According to one embodiment of the present disclosure, a material of the thermosensitive layer is a negative temperature coefficient material, one of the pair of second internal electrodes comprises a first extension, the other one of the pair of second internal electrodes comprises a second extension, and the first extension is disposed between the substrate and the thermosensitive layer, and the second extension is disposed on the thermosensitive layer.

According to one embodiment of the present disclosure, the second extension is a bent structure to extend from a surface of the substrate onto the thermosensitive layer.

The present disclosure provides a manufacturing method of a chip resistor with a temperature sensing function. The manufacturing method includes providing a substrate; disposing a resistive layer on a first portion of the substrate; disposing a thermosensitive layer on a second portion of the substrate; forming a pair of first electrodes on two sides of the resistive layer respectively; and forming a pair of second electrodes on two sides of the thermosensitive layer respectively.

According to one embodiment of the present disclosure, a material of the thermosensitive layer is a negative temperature coefficient material, and manufacturing method further includes disposing a first internal electrode on the second portion of the substrate before disposing the thermosensitive layer on the second portion of the substrate, in which the first internal electrode has a first extension; disposing the thermosensitive layer on the first internal electrode, and the thermosensitive layer covers the first extension of the first internal electrode; and disposing a second internal electrode on the thermosensitive layer.

According to one embodiment of the present disclosure, the second internal electrode has a second extension, and the second extension is a bent structure to extend from a surface of the substrate onto the thermosensitive layer.

According to one embodiment of the present disclosure, manufacturing method further includes disposing a first protective layer on the second internal electrode; and disposing a second protective layer on the first protective layer.

According to one embodiment of the present disclosure, a material of the first protective layer is an insulating glass.

According to one embodiment of the present disclosure, a sintering temperature of the first protective layer is lower than a sintering temperature of the second internal electrode.

### BRIEF DESCRIPTION OF THE DRAWINGS

For a clearer and easier understanding of the above and other objects, features, advantages, and embodiments of the present disclosure, the drawings are described as follow.

FIG. 1 is a schematic diagram of a chip resistor with a temperature sensing function according to an embodiment of the present disclosure.

FIGS. 2A to 2C are schematic diagrams of cross-sections of a chip resistor cut along a dashed line A-A’, a dashed line B-B’ and a dashed line C-C’ shown in FIG. 1, respectively.

FIG. 2D is a top view schematic diagram of the resistive layer and the thermosensitive layer according to an embodiment of the present disclosure.

FIGS. 3A to 3N are three-dimensional schematic diagrams and corresponding top view schematic diagrams of a chip resistor with a temperature sensing function at various stages according to an embodiment of the present disclosure.

FIGS. 4A to 4C are schematic diagrams of cross-sections of a chip resistor cut along the dashed line A-A’, the dashed line B-B’ and the dashed line C-C’ shown in FIG. 1, respectively.

FIG. 4D is a top view schematic diagram of a resistive layer that has not yet formed first electrodes and a thermosensitive layer that has not yet formed second electrodes according to an embodiment of the present disclosure.

FIGS. 5A to 5M are three-dimensional schematic diagrams and corresponding top view schematic diagrams of a chip resistor with a temperature sensing function at various stages according to an embodiment of the present disclosure.

### DETAILED DESCRIPTION

Various different embodiments or examples are provided below for implementing different features of the provided disclosure. The embodiments of components and configurations described below are examples only and are not intended to be restrictive. In addition, for the purpose of simplification and clarity, the present disclosure repeats reference numerals and/or numbers in each example in the present disclosure, and this repetition does not in itself limit the relationship between various embodiments and/or components discussed.

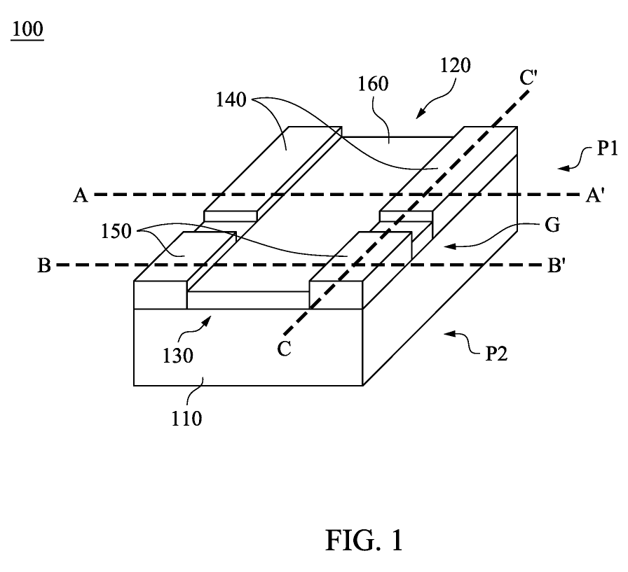

FIG. 1 is a schematic diagram of a chip resistor 100 with a temperature sensing function according to an embodiment of the present disclosure. A first portion P1 of a substrate 110 is provided with a resistive layer 120 and a pair of first electrodes 140, and a second portion P2 of the substrate 110 is provided with a thermosensitive layer 130 and a pair of second electrodes 150. A gap G is between the resistive layer 120 and the thermosensitive layer 130, and a middle portion of the resistive layer 120, a middle portion of the thermosensitive layer 130, and the gap G are covered by a protection layer 160.

The gap G between the resistive layer 120 and the thermosensitive layer 130 results in a gap G between the two first electrodes 140 (which covers the two sides of the resistive layer 120) and between the two second electrodes 150 (which covers the two sides of the thermosensitive layer 130). That is, the resistive layer 120 and the thermosensitive layer 130 are not in contact with each other, and the first electrodes 140 and the second electrodes 150 are not in contact with each other. In a top view perspective (the orientation shown in FIG. 1), the cross-shaped coverage area of the protective layer 160 separates the first electrodes 140 and the second electrodes 150 into four electrodes.

The protective layer 160 prevents the resistive layer 120 and the thermosensitive layer 130 from being contaminated or oxidized by the environment to achieve an insulating protective effect. The material of the protective layer 160 may be an epoxy resin, an acrylic resin, or other insulating materials.

In embodiments of the present disclosure, the material of the substrate 110 may be a ceramic material such as an aluminium oxide (Al₂O₃), an aluminium nitride (AlN), a boron nitride (BN) or a glass (SiO₂). The material of the resistive layer 120 may be a metal alloy material such as a copper-manganese alloy (MnCu), a copper-nickel alloy (CuNi), a copper-manganese-nickel alloy (CuMnNi), a copper-manganese-tin alloy (CuMnSn), a nickel-chromium-aluminium alloy (NiCrAl), a ferrochromium-aluminium alloy (FeCrAl), a tantalum nitride alloy (TaN), and the like.

In embodiments of the present disclosure, the material of the thermosensitive layer 130 may be a material having a positive temperature resistance coefficient or a material having a negative temperature resistance coefficient. In embodiments where the thermosensitive layer 130 has a positive temperature resistance coefficient, the material includes, but is not limited to, a metal having a high positive temperature resistance coefficient such as a nickel (Ni), a copper (Cu), or a platinum (Pt). In embodiments where the thermosensitive 130 has a negative temperature resistance coefficient, the material includes, but is not limited to, a resistive paste made from a manganese oxide (Mn₃O₄), a cobalt oxide (Co₃O₄), a copper oxide (CuO₂), a nickel oxide (NiO), a ruthenium oxide (RuO₂), or a nickel magnesium zinc (NiMgZn) alloy.

In order to better understand the internal structure and manufacturing method of the chip resistor 100 with temperature sensing function of the present disclosure, an embodiment in which the thermosensitive layer 130 of the chip resistor 100 has a positive temperature resistance coefficient and an embodiment in which the thermosensitive layer 130 has a negative temperature resistance coefficient are described below and are referred to and described as a chip resistor 100A and a chip resistor 100B, respectively.

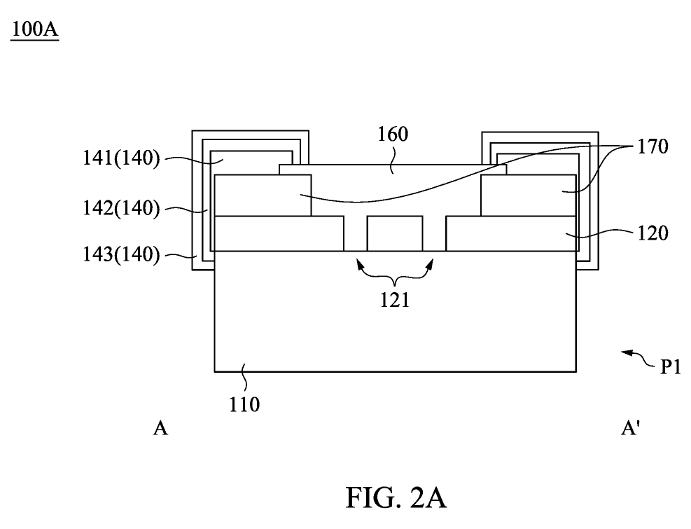

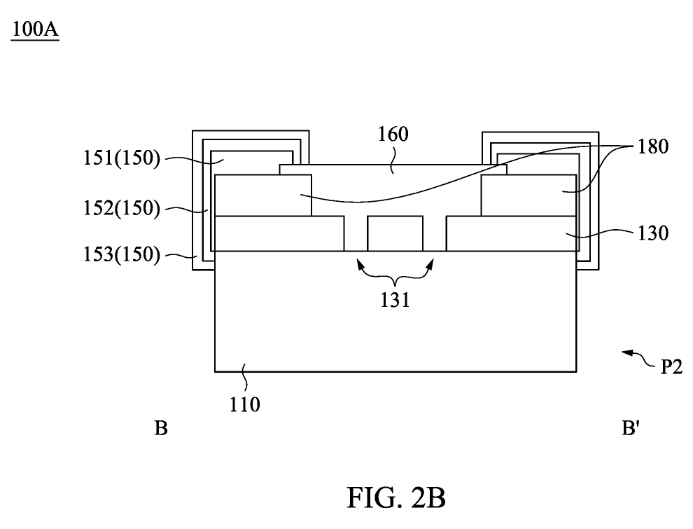

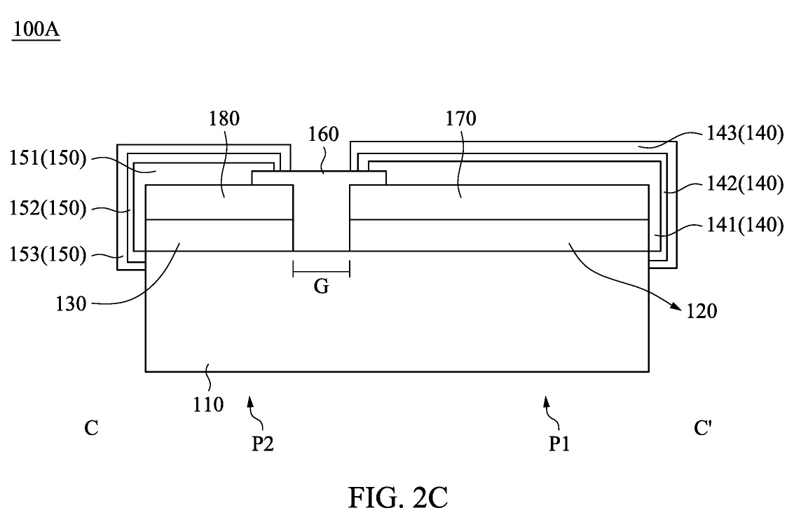

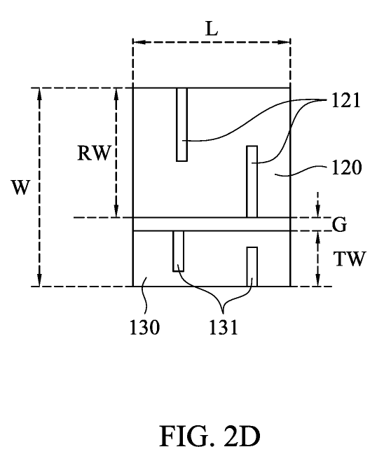

FIGS. 2A to 2C illustrate schematic diagrams of cross-sections of the chip resistor 100A cut along a dashed line A-A’, a dashed line B-B’, and a dashed line C-C’ shown in FIG. 1, respectively.

Referring to FIG. 2A, the resistive layer 120 has a first resistive trimming area 121. The first resistive trimming area 121 is covered by the protective layer 160 and is used to adjust the resistance value to a target resistance value of the resistive layer 120. The chip resistor 100A also includes a pair of first internal electrodes 170 disposed on the resistive layer 120. Each of the first electrodes 140 covering one side of the resistive layer 120 also includes a copper layer 141, a nickel layer 142, and a tin layer 143 formed sequentially by electroplating processes. The outermost tin layer 143 is used to provide solder adhesion between the chip resistor 100A and external circuit boards. Each of the first electrodes 140 extends from the surface of the protective layer 160 and covers the corresponding sidewalls of the first internal electrode 170 and the resistive layer 120. In embodiments of the present disclosure, the copper layer 141 is at least 5 microns thicker than the protective layer 160.

Referring to FIG. 2B, the thermosensitive layer 130 has a second resistive trimming area 131. The second resistive trimming area 131 is covered by the protective layer 160 and is used to adjust the resistance value to a target resistance value of the thermosensitive layer 130. The chip resistor 100A also includes a pair of second internal electrodes 180 disposed on the thermosensitive layer 130. Each of the second electrodes 150 covering one side of the thermosensitive layer 130 also includes a copper layer 151, a nickel layer 152, and a tin layer 153 formed sequentially by electroplating processes. The outermost tin layer 153 is used to provide solder adhesion between the chip resistor 100A and external circuit boards. Each of the second electrodes 150 extends from the surface of the protective layer 160 and covers the corresponding sidewalls of the second internal electrode 180 and the thermosensitive layer 130. In embodiments of the present disclosure, the copper layer 151 is at least 5 microns thicker than the protective layer 160.

Referring to FIG. 2C, it can be more clearly seen that the resistive layer 120 is disposed on the first portion P1 of the substrate 110 and the thermosensitive layer 130 is disposed on the second portion P2 of the substrate 110. A gap G is between the resistive layer 120 and the thermosensitive layer 130, and the gap G is covered by a protective layer 160. The resistive layer 120 and the thermosensitive layer 130 on the substrate 110 are separated by the gap G, and the first internal electrodes 170 (disposed on the resistive layer 120) and the second internal electrodes 180 (disposed on the thermosensitive layer 130) are not in contact with each other, and the first electrodes 140 (covering the first internal electrodes 170) and the second electrodes 150 (covering the second internal electrodes 180) are not in contact with each other.

FIG. 2D is a top view schematic diagram of the resistive layer 120 and the thermosensitive layer 130 according to an embodiment of the present disclosure. In embodiments of the present disclosure, the gap G between the resistive layer 120 and the thermosensitive layer 130 is uniform and is approximately 50 microns to 200 microns. The area of the resistive layer 120 on the substrate 110 is larger than the area of the thermosensitive layer 130, which results in a larger volume of the first electrodes 140 covering the resistive layer 120 than the volume of the second electrodes 150 covering the thermosensitive layer 130. In embodiments of the present disclosure, the width of the substrate is W, the width RW of the resistive layer 120 is about 1/3W to 2/3W, and the width TW of the thermosensitive layer 130 is about 1/5W to 1/4W. The length of the substrate 110 is L, the lengths of the resistive layer 120 and the thermosensitive layer 130 may be the same as the length L of the substrate 110.

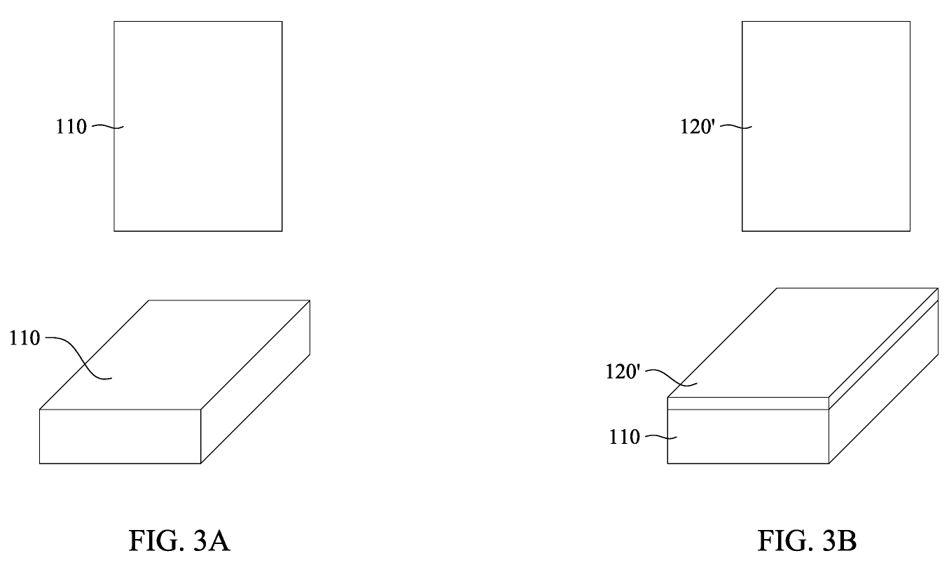

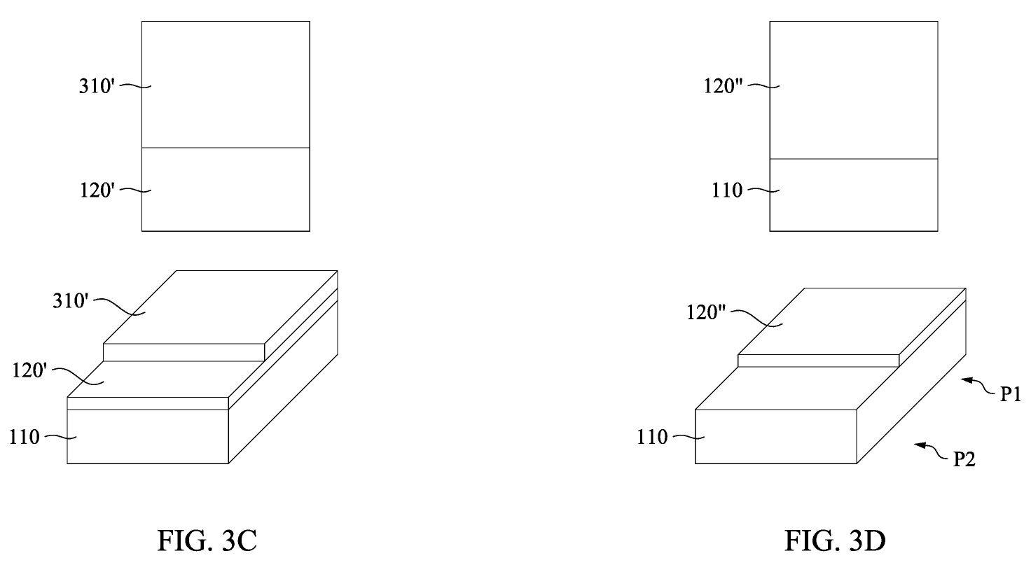

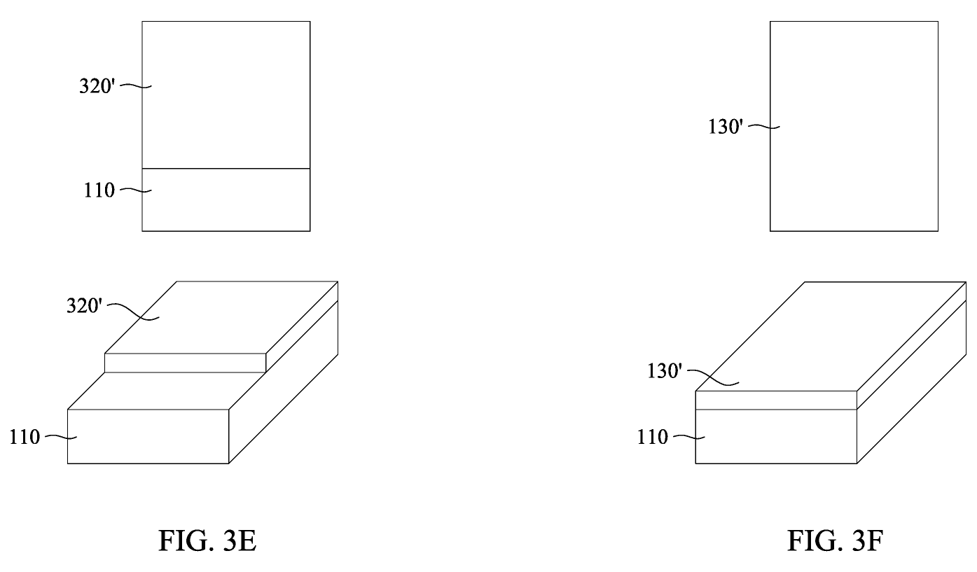

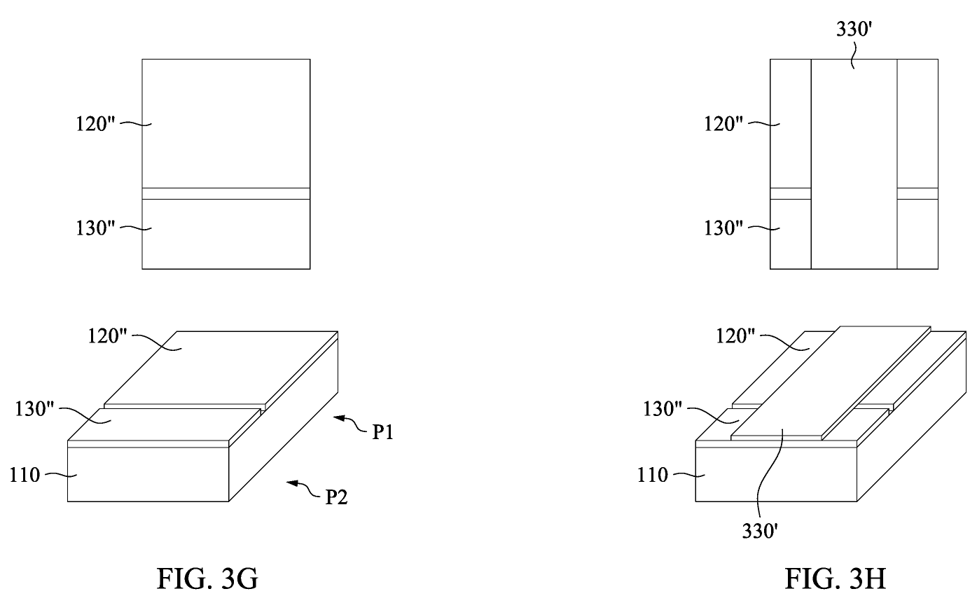

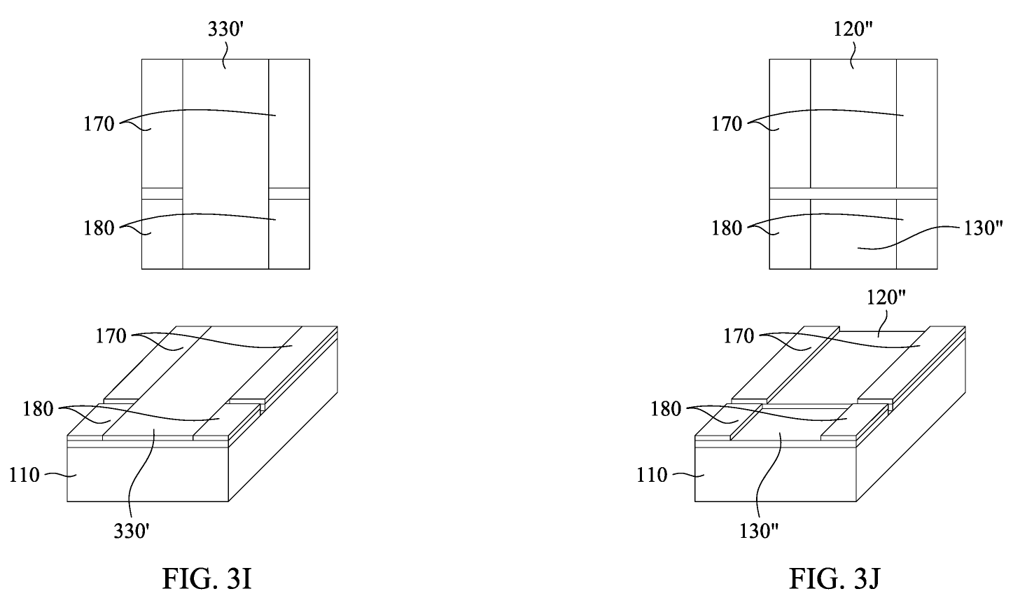

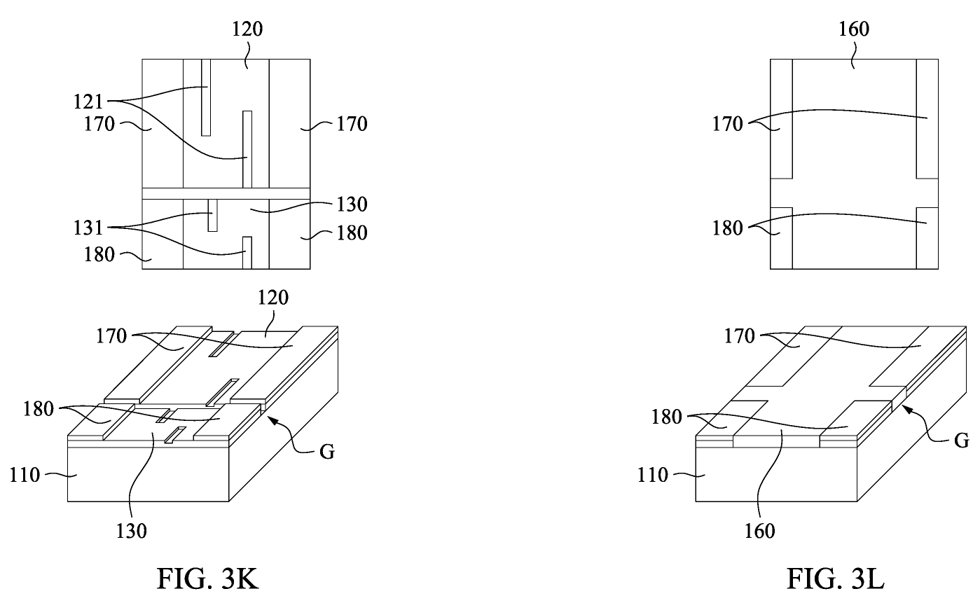

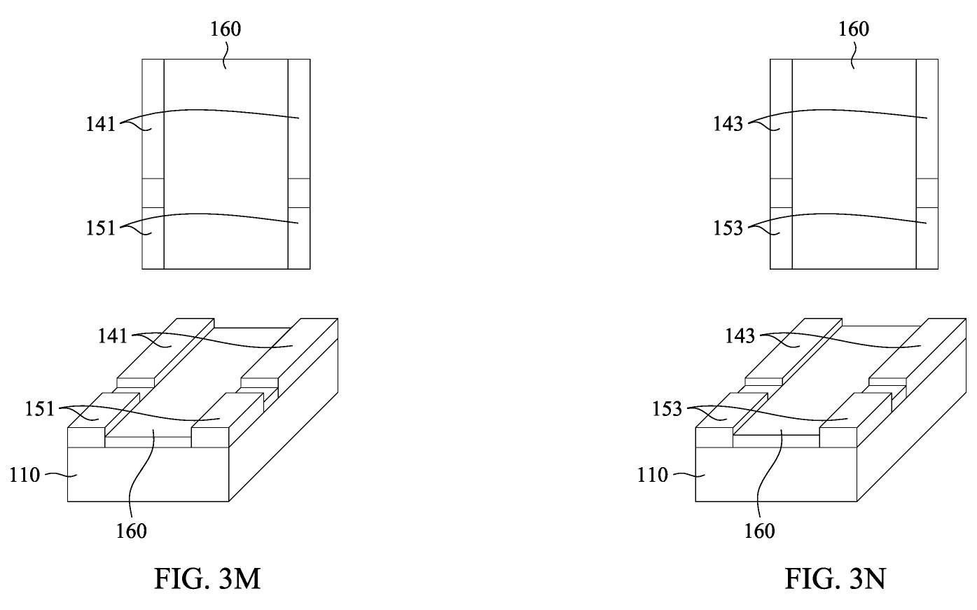

FIGS. 3A to 3N are three-dimensional schematic diagrams and corresponding top view schematic diagrams of the chip resistor 100A with temperature sensing function at various stages according to an embodiment of the present disclosure. Although only some operations are briefly described below, the manufacturing process may in fact include other additional operations, and the manufacturing sequence is not limited thereto. For example, some operations may be performed in a different order, and some additional operations may be modified as appropriate.

In FIG. 3A, a substrate 110 is provided first. In FIG. 3B, an alloy resistive layer 120’ is formed on the substrate 110 by sputtering. In FIG. 3C, a patterned and removable anti-electroplating layer 310’ is overlaid on the alloy resistive layer 120’ by using printing or photolithography processes. The patterned anti-electroplating layer 310’ may be a photoresist layer, a removable adhesive film, or an ink, etc., and the present disclosure is not limited thereto.

In FIG. 3D, a portion of the alloy resistive layer 120’, which is not covered by the anti-electroplating layer 310’, is removed by using an etching process, a film removal solvent, or a wet stripping process, and the surface of the second portion P2 of the substrate 110 is exposed. The alloy resistive layer 120’ covered by the anti-electroplating layer 310’ is retained on the first portion P1 of the substrate 110 to become an alloy resistive layer 120’’. In FIG. 3E, a patterned and removable photoresist layer 320’, which may be a removable film or ink, etc., is overlaid on the alloy resistive layer 120’’ by using printing or photolithography processes.

In FIG. 3F, a metal resistive layer 130’ having a positive temperature resistance coefficient is sputtered on the photoresist layer 320’. In FIG. 3G, the photoresist layer 320’ is removed by using an etching process, a film removal solvent, or a wet stripping process to expose the alloy resistive layer 120’’ below the photoresist layer 320’. The metal resistive layer 130’ retained on the second portion P2 of the substrate 110 is formed as a metal resistive layer 130’’. In FIG. 3H, a patterned and removable photoresist layer (or an ink) 330’ is overlaid on the middle portions of the alloy resistive layer 120’’ and the metal resistive layer 130’’ by using printing or photolithography processes, and each of the alloy resistive layer 120’’ and the metal resistive layer 130’’ exposes areas for the internal electrodes to be electroplated.

In FIG. 3I, a pair of internal electrodes is electroplated in the areas exposed by each of the alloy resistive layer 120’’ and the metal resistive layer 130’’ by using an electroplating process. The internal electrodes covering two sides of the alloy resistive layer 120’’ are the first internal electrodes 170, and the internal electrodes covering two sides of the metal resistive layer 130’’ are the second internal electrodes 180. In FIG. 3J, the photoresist layer 330’ is removed by an etching process, a film removal solvent, or a wet stripping process to expose underlying alloy resistive layer 120’’ and metal resistive layer 130’’.

In FIG. 3K, a resistance adjustment operation is performed by using a laser trimming process or a physical processing process to obtain a desired target resistance value of the alloy resistive layer 120’’ and the metal resistive layer 130’’. In the resistive trimming process, the alloy resistive layer 120’’ and the metal resistive layer 130’’ are cut to each form a plurality of grooves therein and serve as the first resistive trimming area 121 and the second resistive trimming area 131, respectively. Thus, the alloy resistive layer 120’’ is formed as the resistive layer 120 shown in FIG. 2A, FIG. 2C, and FIG. 2D, and the metal resistive layer 130’’ is formed as the thermosensitive layer 130 shown in FIG. 2B, FIG. 2C, and FIG. 2D.

In FIG. 3L, a protective layer 160 is covered on the gap G, on the resistive layer 120 not covered by the first internal electrodes 170, and on the thermosensitive layer 130 not covered by the second internal electrodes 180 by using printing or photolithography processes. In FIG. 3M, a copper layer 141 and a copper layer 151 are formed by using an electroplating process. The copper layer 141 covers the corresponding side walls of the first internal electrodes 170 and the resistive layer 120 below the first internal electrodes 170. The copper layer 151 covers the corresponding side walls of the second internal electrodes 180 and the thermosensitive layer 130 below the second internal electrodes 180. In FIG. 3N, a nickel layer 142 (not shown) and a tin layer 143 are sequentially formed to cover the copper layer 141, and a nickel layer 152 (not shown) and a tin layer 153 are sequentially formed to cover the copper layer 151 by using electroplating processes. The chip resistor 100A is essentially complete at this stage.

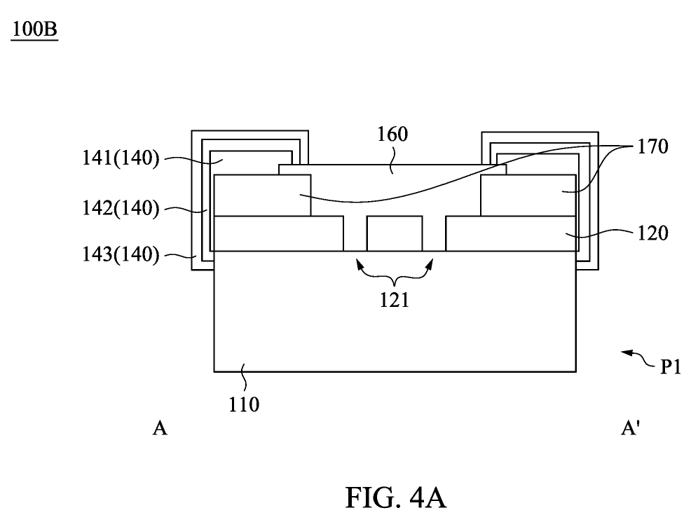

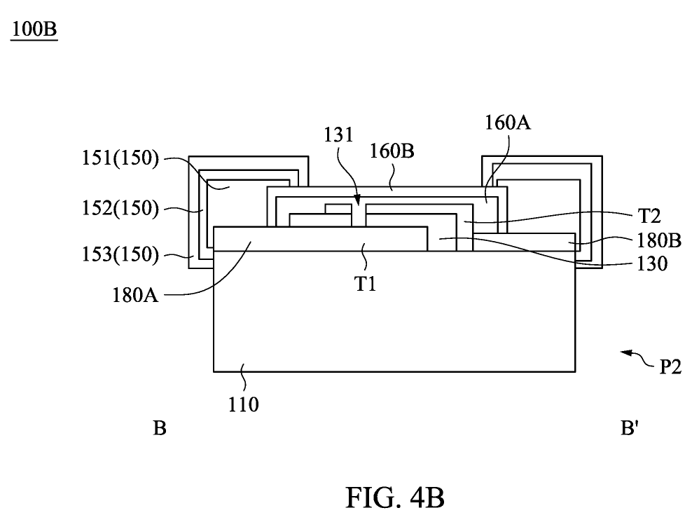

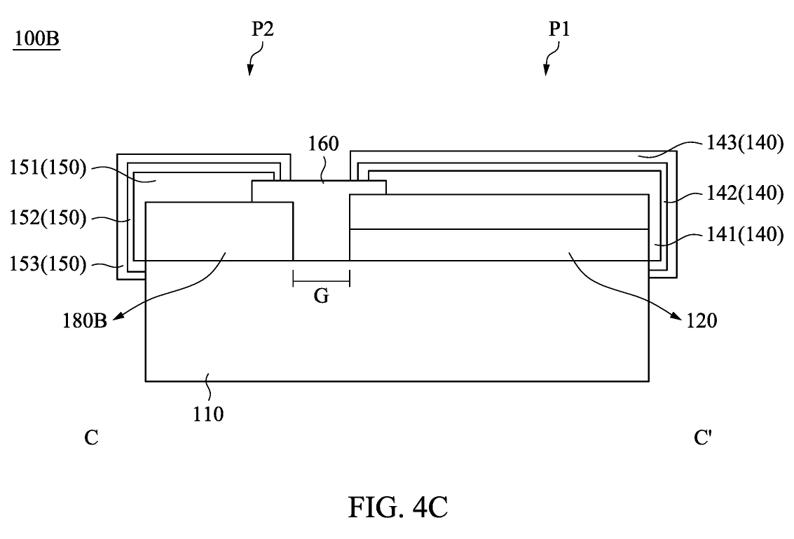

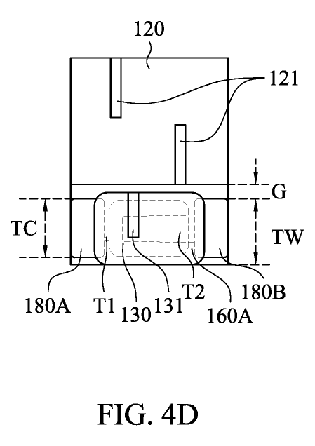

FIGS. 4A to 4C are schematic diagrams of cross-sections of the chip resistor 100B cut along the dashed line A-A’, the dashed line B-B’ and the dashed line C-C’ shown in FIG. 1, respectively. FIG. 4A is similar to FIG. 2A for the chip resistor of 100A, so the details will not be repeated here.

Referring to FIG. 4B, unlike the chip resistor 100A, the internal electrodes of the chip resistor 100B are not all disposed on the thermosensitive layer 130. The internal electrodes in the second portion P2 of the substrate 110 include an internal electrode 180A and an internal electrode 180B. The internal electrode 180A is disposed on the substrate 110, and the thermosensitive layer 130 is disposed between the internal electrode 180A and the internal electrode 180B. The internal electrode 180A has a first extension T1 and is substantially covered by the thermosensitive layer 130 thereon. The foregoing “substantially covered” includes the situation where a slight portion of the first extension T1 may not be covered by the thermosensitive layer 130 without affecting the operation and function of the chip resistor 100B. The internal electrode 180B has a second extension T2, and the second extension T2 is a bent structure for extending from the surface of the substrate 110 over the thermosensitive layer 130.

The protective layer in the second portion P2 of the substrate 110 includes a first protective layer 160A and a second protective layer 160B. The first protective layer 160A completely covers an area range of the thermosensitive layer 130 and covers portions of the internal electrode 180A and the internal electrode 180B. The first protective layer 160A may be made of a glass, and the second protective layer 160B may be made of the same material as the protective layer 160, such as an epoxy resin, an acrylic resin, or other insulating materials. The second electrodes 150 also includes a copper layer 151, a nickel layer 152, and a tin layer 153 formed sequentially by using electroplating processes.

Referring to FIG. 4C, there is also a gap G between the resistive layer 120 and the thermosensitive layer 130, which is covered by the protective layer 160. The gap G separates the resistive layer 120 and the thermosensitive layer 130 on the substrate 110 from each other, and prevents the first electrodes 140 covering the resistive layer 120 and the second electrodes 150 covering the thermosensitive layer 130 from contacting each other.

FIG. 4D is a top view schematic diagram of a resistive layer 120 that has not yet formed first electrodes 140 and a thermosensitive layer 130 that has not yet formed second electrodes 150 according to an embodiment of the present disclosure, in which the thermosensitive layer 130, a portion of the internal electrode 180A and a portion of the internal electrode 180B are covered by the first protective layer 160A. In embodiments of the present disclosure, the first extension T1 and the second extension T2 may have the same or different shapes or configurations, and the present disclosure is not limited thereto. The thermosensitive layer 130 substantially covers the first extension T1, and the second extension T2 is disposed on the thermosensitive layer 130.

In some embodiments of the present disclosure, the gap G between the resistive layer 120 and the thermosensitive layer 130 is uniform and is approximately 50 microns to 200 microns. In some embodiments, the second resistive trimming area 131 may be formed after covering the first protective layer 160A, such that the first protective layer 160A and the underlying thermosensitive layer 130 collectively form the second resistive trimming area 131. In some embodiments, the second resistive trimming area 131 may be formed prior to covering the first protective layer 160A, such that the second resistive trimming area 131 is formed only on the thermosensitive layer 130 and the second extension T2 of the internal electrode 180B.

The area of the resistive layer 120 is larger than the area of the thermosensitive layer 130 on the substrate 110, which results in a larger volume of the first electrodes 140 covering the resistive layer 120 than the volume of the second electrodes 150 covering the thermosensitive layer 130. In embodiments of the present disclosure, the width of the substrate 110 is W, and the width TC of the internal electrode 180A and the internal electrode 180B is about 1/5 to 1/4 of the width W of the substrate 110. The edge of the internal electrode 180A (or the edge of the internal electrode 180B) to the edge of the substrate 110 are width TW, and the width TW may be the same as, or slightly larger than, the width TC.

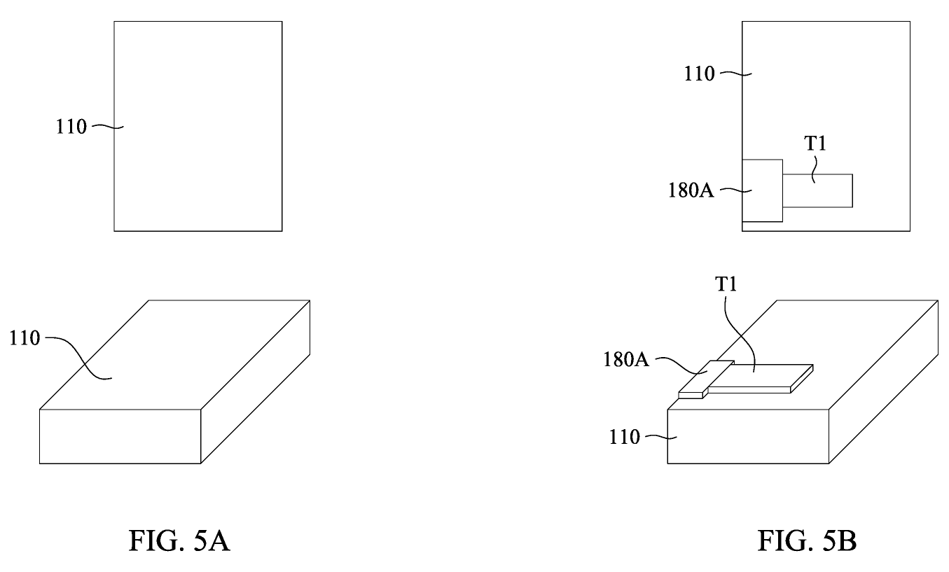

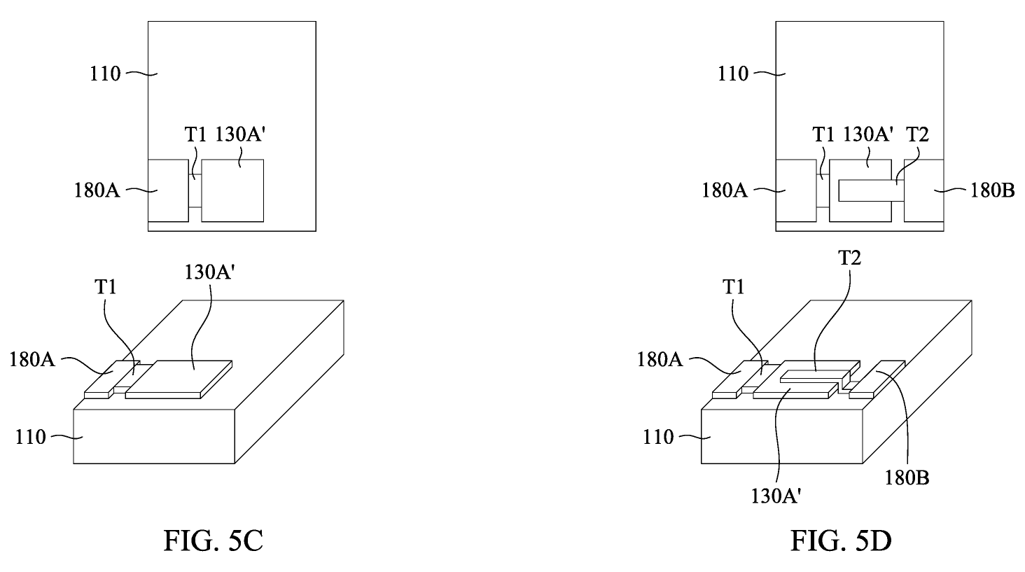

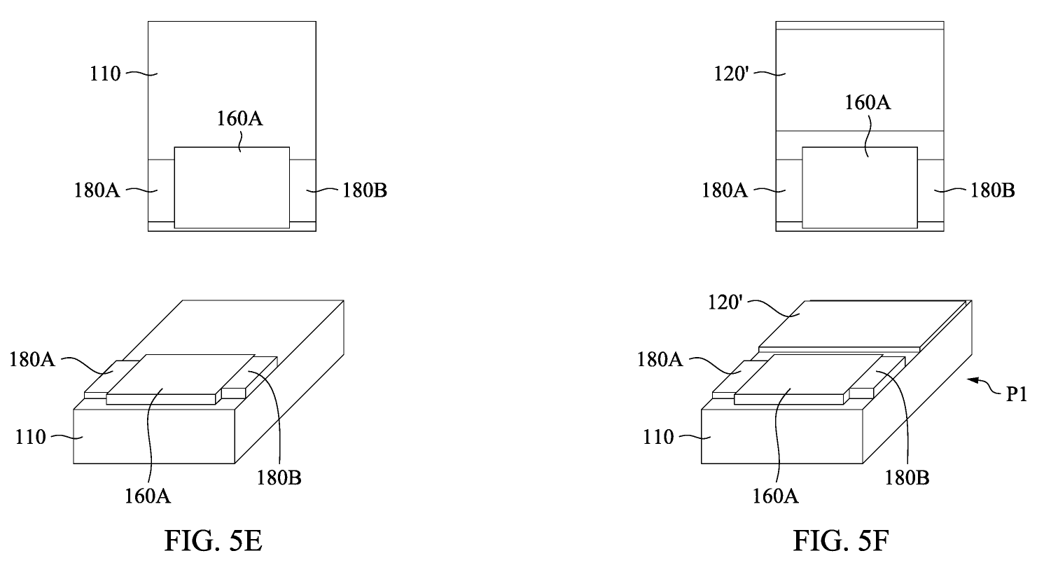

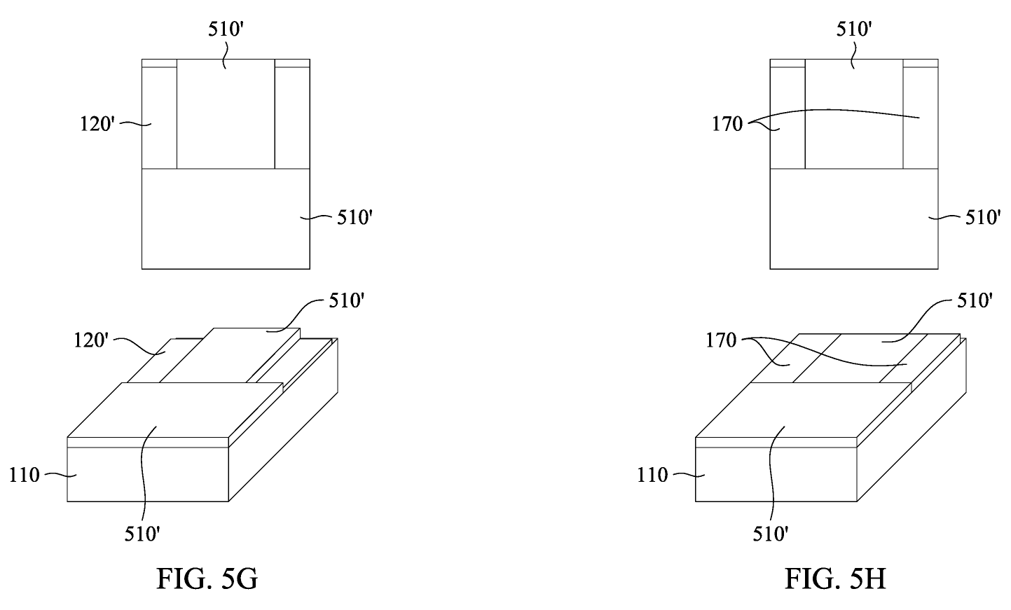

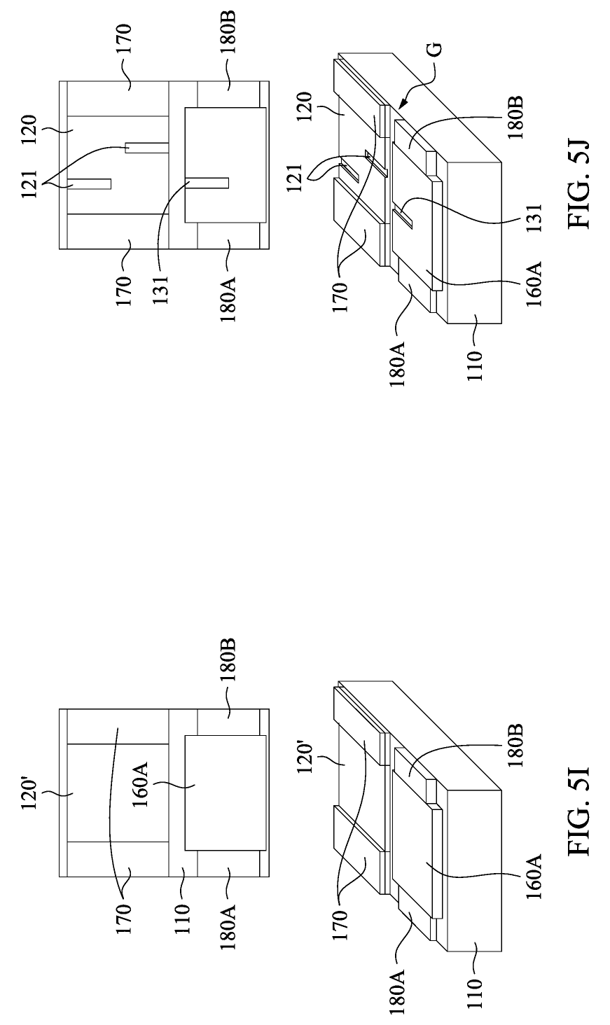

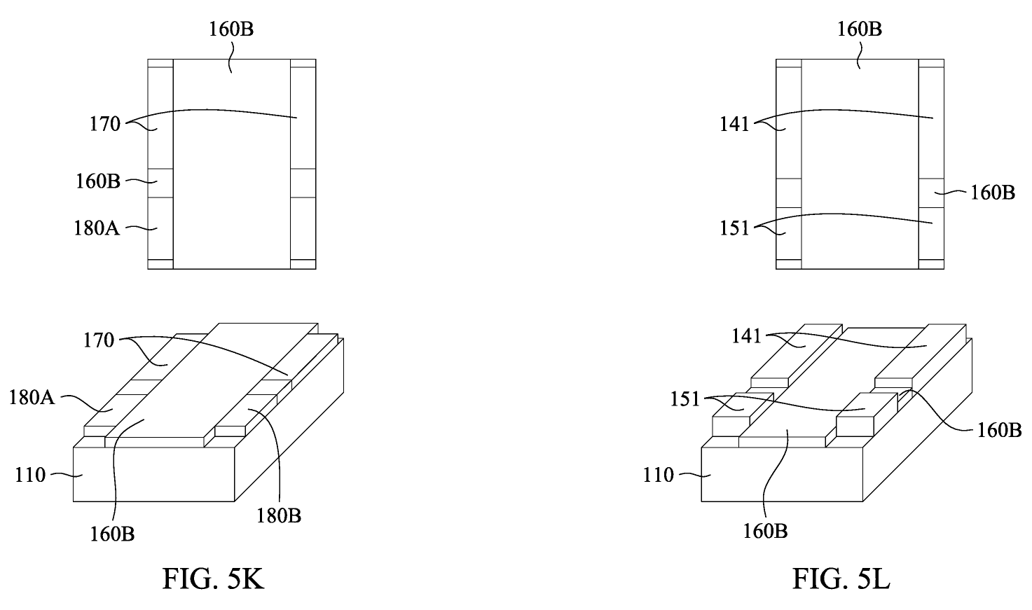

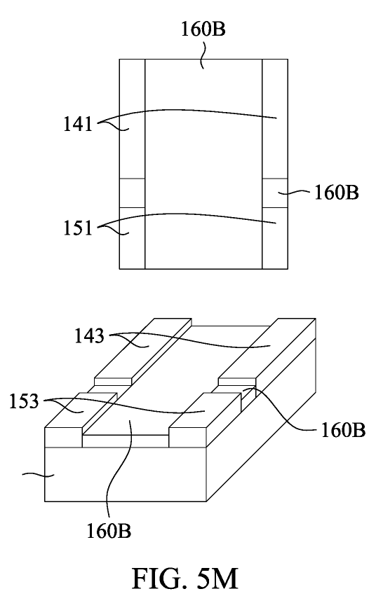

FIGS. 5A to 5M are three-dimensional schematic diagrams and corresponding top view schematic diagrams of the chip resistor 100B with temperature sensing function at various stages according to an embodiment of the present disclosure. Although only some operations are briefly described below, the manufacturing process may in fact include other additional operations, and the manufacturing sequence is not limited thereto. For example, some operations may be performed in a different order, and some additional operations may be modified as appropriate.

In FIG. 5A, a substrate 110 is provided first. In FIG. 5B, a layer of conductive paste is printed on the substrate 110 by using a printing process, and the printed conductive paste is placed in a drying oven to form an internal electrode 180A having a first extension T1. In embodiments of the present disclosure, the baking temperature in the drying oven is between 100°C and 200°C. In embodiments of the present disclosure, the conductive paste may be made of materials such as glass, silver (Ag) and some oxides.

In FIG. 5C, a thermosensitive layer 130A’ is formed (or printed) on the internal electrode 180A. The thermosensitive layer 130A’ substantially covers the first extension T1 of the internal electrode 180A.

In FIG. 5D, a layer of conductive paste is printed on the thermosensitive layer 130A’ and on a terminal opposite to the internal electrode 180A by a printing process, and the printed conductive paste is placed in the drying oven to form an internal electrode 180B having a second extension T2. In embodiments of the present disclosure, the baking temperature in the drying oven is between 100°C and 200°C. In embodiments of the present disclosure, the conductive paste may be made of materials such as glass, silver (Ag) and some oxides.

After completion of the above steps, the semi-finished product is sintered in a high-temperature sintering furnace. In the embodiment of the present disclosure, the sintering temperature of the high-temperature sintering furnace is set at about 600°C to 880°C.

In FIG. 5E, after forming the internal electrode 180B, the first protective layer 160A covers the internal electrode 180B by using a printing process. The material of the first protective layer 160A may be an insulating glass, and the sintering temperature of the first protective layer 160A needs to be slightly lower than the sintering temperature of the internal electrode 180B, which is about 450°C to 650°C. In FIG. 5F, an alloy resistive layer 120’ is formed on the first portion P1 of the substrate 110 by using sputtering. In FIG. 5G, a patterned and removable photoresist layer 510’ covers the middle area of the alloy resistive layer 120’, the internal electrode 180A, the internal electrode 180B, and the first protective layer 160A by using printing or photolithography processes, exposing only the areas of a pair of internal electrodes to be electroplated on two sides of the alloy resistive layer 120’.

In FIG. 5H, electroplating the pair of internal electrodes in the areas exposed by the alloy resistive layer 120’ by using an electroplating process to form the first internal electrodes 170.

In FIG. 5I, the photoresist layer 510’ is removed by an etching process, a film removal solvent, or a wet stripping process to expose the alloy resistive layer 120’, the internal electrode 180A, the internal electrode 180B, and the first protective layer 160A underneath.

In FIG. 5J, a resistance adjustment operation is performed by using a laser trimming process or a physical processing process to form a first resistive trimming area 121 on the alloy resistive layer 120’’ and a second resistive trimming area 131 on the first protective layer 160A (including the thermosensitive layer 130A’ underneath). Although the second resistive trimming area 131 is drawn on the first protective layer 160A in FIG. 5J, the second resistive trimming area 131 may actually be formed directly on the thermosensitive layer 130A’. Thus, the alloy resistive layer 120’’ is formed as the resistive layer 120 shown in FIG. 4A, FIG. 4C, and FIG. 4D, and the thermosensitive layer 130A’ is formed as the thermosensitive layer 130 shown in FIG. 4B, FIG. 4C, and FIG. 4D.

In FIG. 5K, a second protective layer 160B is overlaid on a portion of the resistive layer 120 which are not covered by the first internal electrodes 170, the thermosensitive layer 130 (which may be regarded as the thermosensitive layer 130 and the first protective layer 160A) and the gap G, by using printing or photolithography processes. In embodiments of the present disclosure, the second protective layer 160B also covers a portion of the first internal electrodes 170.

In FIG. 5L, a copper layer 141 and a copper layer 151 are formed by using an electroplating process. The copper layer 141 covers the corresponding side walls of the first internal electrodes 170 and the resistive layer 120, and the copper layer 151 covers the corresponding side walls of the internal electrode 180A and the internal electrode 180B.

In FIG. 5M, a nickel layer 142 (not shown) and a tin layer 143 are sequentially formed to cover the copper layer 141, and a nickel layer 152 (not shown) and a tin layer 153 are sequentially formed to cover the copper layer 151 by using electroplating processes. The chip resistor 100A is essentially complete at this stage.

According to the chip resistor with temperature sensing function and the manufacturing method thereof of the present disclosure, a resistive layer and a thermosensitive layer are respectively provided on the first portion and the second portion on the same surface of the substrate, so that the chip resistor may serve as an electrical sensing element and simultaneously measure the ambient temperature (or the temperature of the chip resistor itself) with a high degree of accuracy. In conclusion, the chip resistor with temperature sensing function of the present disclosure realizes ambient temperature measurement and current measurement by integrating two resistive layers on the same substrate, which reduces the size of the components and increases the layout space of the circuit board while improving the accuracy of temperature sensing.

Although the present disclosure has been disclosed as above in embodiments, the embodiments are not intended to limit the present disclosure, and those of ordinary skill in the art may make some changes and embellishments within the spirit and scope of the present disclosure, therefore, the scope of protection of the present disclosure shall be defined in the attached Claims.

What is claimed is:

1. A chip resistor with a temperature sensing function, comprising:
a substrate;
a resistive layer disposed on a first portion of the substrate;
a thermosensitive layer disposed on a second portion of the substrate, wherein a gap is between the resistive layer and the thermosensitive layer;
a pair of first electrodes respectively covering two sides of the resistive layer; and
a pair of second electrodes respectively covering two sides of the thermosensitive layer.

2. The chip resistor according to claim 1, wherein a material of the thermosensitive layer is a positive temperature coefficient material.

3. The chip resistor according to claim 1, wherein a material of the thermosensitive layer is a negative temperature coefficient material.

4. The chip resistor according to claim 1, wherein a distance of the gap is from 50 microns to 200 microns.

5. The chip resistor according to claim 4, wherein the gap is uniform.

6. The chip resistor according to claim 1, further comprising:
a protective layer covering a portion surface of the resistive layer, a portion surface of the thermosensitive layer, and the gap.

7. The chip resistor according to claim 6, wherein each of the pair of first electrodes comprises:
a copper layer, wherein the copper layer is at least 5 microns thicker than the protective layer.

8. The chip resistor according to claim 1, wherein an area of the resistive layer is larger than an area of the thermosensitive layer in a frontal view.

9. The chip resistor according to claim 1, wherein a volume of each of the pair of first electrodes is greater than a volume of each of the pair of second electrodes.

10. The chip resistor according to claim 1, wherein the resistive layer has a first resistive trimming area.

11. The chip resistor according to claim 10, wherein the thermosensitive layer has a second resistive trimming area.

12. The chip resistor according to claim 1, further comprising:
a pair of first internal electrodes contacting the resistive layer and respectively covered by the pair of first electrodes; and
a pair of second internal electrodes contacting the thermosensitive layer and respectively covered by the pair of second electrodes.

13. The chip resistor according to claim 12, wherein a material of the thermosensitive layer is a negative temperature coefficient material, one of the pair of second internal electrodes comprises a first extension, the other one of the pair of second internal electrodes comprises a second extension, and wherein the first extension is disposed between the substrate and the thermosensitive layer, and the second extension is disposed on the thermosensitive layer.

14. The chip resistor according to claim 13, wherein the second extension is a bent structure to extend from a surface of the substrate onto the thermosensitive layer.

15. A manufacturing method of a chip resistor with a temperature sensing function, comprising:
providing a substrate;
disposing a resistive layer on a first portion of the substrate;
disposing a thermosensitive layer on a second portion of the substrate;
forming a pair of first electrodes on two sides of the resistive layer respectively; and
forming a pair of second electrodes on two sides of the thermosensitive layer respectively.

16. The manufacturing method according to claim 15, wherein a material of the thermosensitive layer is a negative temperature coefficient material, and manufacturing method further comprising:
disposing a first internal electrode on the second portion of the substrate before disposing the thermosensitive layer on the second portion of the substrate, wherein the first internal electrode has a first extension;
disposing the thermosensitive layer on the first internal electrode, wherein the thermosensitive layer covers the first extension of the first internal electrode; and
disposing a second internal electrode on the thermosensitive layer.

17. The manufacturing method according to claim 16, wherein the second internal electrode has a second extension, the second extension is a bent structure to extend from a surface of the substrate onto the thermosensitive layer.

18. The manufacturing method according to claim 17, further comprising:
disposing a first protective layer on the second internal electrode; and
disposing a second protective layer on the first protective layer.

19. The manufacturing method according to claim 18, wherein a material of the first protective layer is an insulating glass.

20. The manufacturing method according to claim 19, wherein a sintering temperature of the first protective layer is lower than a sintering temperature of the second internal electrode.
